(19) United States
(12) Patent Application Publication
(10) Pub. No.: US 2026/0237407 A1
(43) Pub. Date: Aug. 13, 2026

(54) INTEGRATED CIRCUIT DEVICE AND METHOD OF MANUFACTURE

(71) Applicant: Taiwan Semiconductor Manufacturing Company, Ltd., Hsinchu (TW)

(72) Inventors: Chen-Jun Wu, Hsinchu City (TW); Chieh-Fang Chen, Hsinchu County (TW); Katherine H. Chiang, New Taipei City (TW); Chung-Te Lin, Tainan City (TW)

(21) Appl. No.: 19/254,648

(22) Filed: Jun. 30, 2025

Related U.S. Application Data
(60) Provisional application No. 63/757,358, filed on Feb. 12, 2025.

(51) Int. Cl. G11C 5/06; G11C 11/4091; G11C 11/4096; H01L 23/00; H10B 12/00; H10D 80/30

(52) U.S. Cl. CPC G11C 5/063; G11C 11/4091; G11C 11/4096; H10B 12/482; H10B 12/488; H10B 12/50; H10D 80/30; H10W 90/792

(57) ABSTRACT

A memory device includes a single logic die bonded with multiple memory dies, each memory die containing arrays of 1T1C memory cells of the type formed using back-end-of-line processing. Each memory die can include multiple vertically stacked tiers of the memory cells. Control circuits for the memory cells, including sense amplifiers and column drivers, are in the logic die. The logic die has a substrate and the memory die opposite the logic die has a substrate, but the substrates of the middle dies are absent having been removed during processing. Switches may be provided to isolate bitline segments, reducing parasitic capacitance and removing a constraint on the number of memory cell tiers that can be operated using the single logic die.

### REFERENCE TO RELATED APPLICATION

This Application claims priority to U.S. Provisional Application no. 63/757,358, filed on Feb. 12, 2025, the contents of which are hereby incorporated by reference in their entirety.

### BACKGROUND

Dynamic random-access memory (DRAM) is a widely used semiconductor memory technology recognized for its high-speed operation and low cost per bit. It is an essential component in a variety of computing and electronic devices. The semiconductor industry has continuously sought innovations aimed at improving the density of DRAM and other memory technologies. One significant advancement has involved transitioning from traditional memory cell structures that are manufactured using front-end-of-line (FEOL) processing to memory cell structures that are manufactured using back-end-of-line (BEOL) processing. When DRAM cells are made with FEOL processing, they are all in one plane. BEOL DRAM cells may be distributed among a plurality of tiers in a three-dimensional (3D) memory structure. Despite these developments, there remains a persistent demand for further innovations to increase memory density, reduce power consumption, and enhance overall performance.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a perspective view of a memory device according to some aspects of the present disclosure.

FIG. 1A illustrates the connectivity within a memory die of the memory device of FIG. 1.

FIGS. 2A to 2G illustrate strings of 1T1C memory cells according to various embodiments of the present disclosure.

FIG. 3 provides a circuit diagram for a 1T1C memory cell.

FIGS. 4-6 provides circuit diagrams for various embodiments.

FIG. 7 illustrates a string of 1T1C memory cells with a switch according to an embodiment of the present disclosure.

FIGS. 8, 8A, 8B-14 provide a series of cross-sectional views illustrating a process of the present disclosure.

FIGS. 15-24 provide cross-sectional views illustrating variations on the process of FIGS. 8A-14.

FIG. 25 provides a flow chart for a process of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

One aspect of the present disclosure relates to a memory device in which memory cells and their associated logic circuits (e.g., sense amplifiers and word line drivers) are fabricated on separate wafers that are bonded together prior to wafer singulation (dicing). The inventors have recognized that directly integrating back-end-of-line (BEOL) memory cells over front-end-of-line (FEOL) logic circuits reduces the reliability of the logic circuits, particularly at advanced semiconductor technology nodes. Manufacturing BEOL metal interconnect structures containing memory cells typically involves higher temperature processing steps, resulting in a greater thermal budget compared to BEOL interconnect structures composed only of wiring, passivation, and bonding materials. This reliability concern is particularly acute with advanced transistor technologies such as fin field-effect transistors (FinFETs), which enable increased circuit density.

In some embodiments, the memory device includes a single logic die bonded with multiple memory dies, each containing arrays of BEOL memory cells. In certain embodiments, each memory die includes multiple vertically stacked tiers of memory cells. Integrating multiple memory tiers within each individual die reduces the number of bonding layers required and decreases the overall package height compared to configurations where each memory tier occupies a separate die. On the other hand, integrating too many memory tiers on a single wafer increases the difficulty of controlling wafer warpage during fabrication. By utilizing multiple memory device wafers instead of a single wafer to distribute memory cells, a greater number of tiers can be accommodated.

Another aspect of the present disclosure relates to memory dies configured with a lower bonding tier on one side (face), an upper bonding tier on the opposite side, and no intervening substrate. Each tier of these memory dies, including bonding tiers, metallization tiers, and memory tiers, comprises dielectric material resulting in a continuous composite dielectric structure extending through the entire thickness of each memory die. When multiple substrate-free memory dies are bonded together into a stack, this composite dielectric structure extends continuously through the entire stack. The substrate-free memory dies are fabricated by removing original substrates after wafer-to-wafer bonding. Eliminating the substrates significantly reduces die thickness, enabling a greater number of stacked dies without substantially increasing the overall package height.

In some embodiments, switches integrated within the memory dies isolate segments of bitlines controlling individual strings of memory cells. These switches may be BEOL transistors formed in the same tier—and fabricated simultaneously—with transistors of the one-transistor, one-capacitor (1T1C) memory cells. Groups of bitline segment are coupled to bitlines each having a dedicated sense amplifier. When a memory device includes only a single logic die, the area available on that logic die limits the total number of sense amplifiers. As additional memory cell tiers are integrated vertically, more memory cells are connected to each bitline resulting in increased parasitic capacitance. Eventually, excessive parasitic capacitance can overshadow the capacitance of individual 1T1C memory cells, hindering reliable detection of the cells' programmed state. The present disclosure addresses this limitation by incorporating switches into the memory dies that selectively isolate bitline segments, thereby reducing parasitic capacitance and removing a constraint on the number of memory tiers manageable by a single logic die sharing the same footprint as the memory dies.

Further aspects of the disclosure pertain to processes for fabricating the memory devices described above. These processes typically begin with the fabrication of a logic device wafer and multiple memory device wafers. The logic device wafer includes a semiconductor substrate and integrated logic circuits, such as sense amplifiers and word line drivers, formed on the substrate. A BEOL metal interconnect structure is formed on the logic wafer, with a bonding layer provided on top. In some embodiments, the logic wafer does not include memory cells.

The memory device wafers initially include a substrate (e.g., a semiconductor substrate). Fabrication of these wafers involves BEOL processing steps but can exclude FEOL processing. The BEOL processing produces a structure comprising, in order, a first redistribution layer (RDL), one or more tiers of memory cells, a second RDL, and a bonding layer. Each RDL includes one or more metallization layers configured for electrical connections.

One memory device wafer is inverted and bonded either to the logic wafer (logic-first process flow) or to another memory device wafer (logic-last process flow). Following bonding, the substrate of the inverted memory device wafer is entirely removed, typically by grinding or similar techniques. A bonding layer may subsequently be formed on the exposed surface, or alternatively, the bonding layer may already be present as part of the BEOL structure, originally positioned between the first RDL and the substrate, and thus exposed upon substrate removal. Additional memory device wafers are sequentially added in the same manner until all memory device wafers are stacked. In the logic-last process flow, the logic wafer is inverted and bonded to the topmost memory device wafer. In the logic-first process flow, the substrate of the last-added memory device wafer is allowed to remain. In the logic-last process flow, the substrate of the first memory device wafer is allowed to remain.

This fabrication approach results in a stack wherein memory cells are embedded in a composite dielectric structure that extends between two substrates: one associated with the logic wafer, and the other associated with the first or last memory device wafer in the stack. The composite dielectric structure comprises dielectric materials from metallization layers (RDLs), memory tiers, and bonding layers.

Finally, the logic wafer's semiconductor substrate is thinned, and through-substrate vias (TSVs) are formed. Routing structures, passivation layers, solder bumps, or similar features are subsequently added on the logic substrate's back side. The completed wafer stack is then singulated (diced) to yield a plurality of memory devices according to the present disclosure.

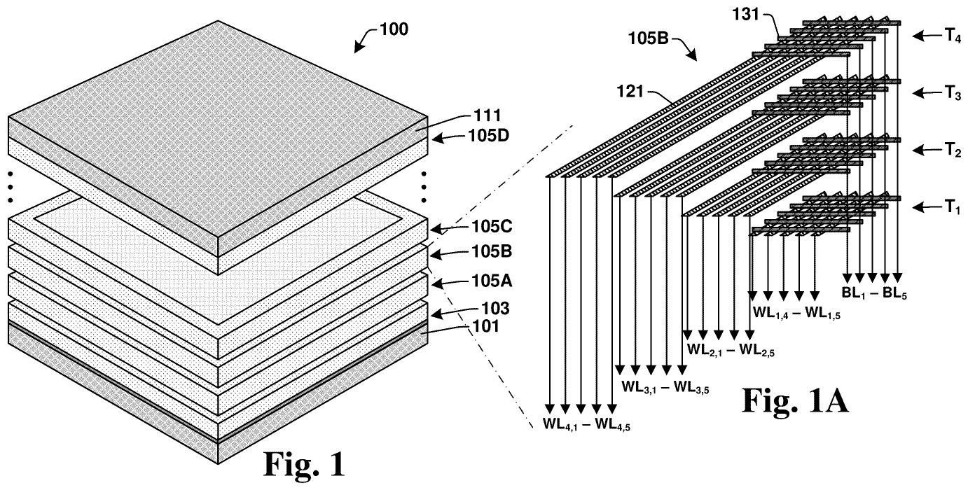

FIG. 1 illustrates a perspective view of a memory device 100 according to an embodiment of the present disclosure. The memory device 100 includes a logic device layer 103 and multiple memory device layers 105A-105D bonded together in a vertical stack. The logic device layer 103 includes a semiconductor substrate 101, and the topmost memory device layer 105D includes a substrate 111. The intermediate memory device layers 105A-105C are substrate-free and form a continuous dielectric structure extending vertically between the semiconductor substrate 101 and the substrate 111.

FIG. 1A illustrates an exemplary arrangement of bitline segments 131 and word line segments 121 within one of the memory device layers (e.g., memory device layer 105B). Memory cells (not shown) are located at junctures between the bitline segments 131 and the word line segments 121. As illustrated in FIG. 1A, each memory device layer includes memory cells organized into arrays having m rows, n columns, and k tiers. For illustrative purposes, the memory device 100 depicted in FIG. 1 comprises four memory device layers 105A-105D, each including a 3D memory array of five rows, five columns, and four tiers. These dimensions are provided only as examples and are not intended to be limiting. The bitline segments 131 connect to bitlines BL₁-BL₅, with one bitline segment 131 provided for each row. The bitlines BL₁-BL₅ are shared across memory tiers T₁-T₄. There is one word line segment 121 for each combination of row and tier, with each word line segment typically coupled to a distinct one of the word lines WL_{1,1} through WL_{4,5}.

In general, the memory device 100 comprises j memory device layers 105, with each layer including k memory cell tiers, resulting in a total number of memory tiers equal to j×k. In some embodiments, the memory device 100 includes between two and five total memory cell tiers. In other embodiments, the memory device 100 comprises between six and twelve memory cell tiers, and in yet other embodiments, more than twelve memory cell tiers. The use of multiple memory tiers increases memory storage capacity. The present disclosure provides fabrication techniques and structural configurations to effectively control wafer warpage, device height, and parasitic capacitance, enabling six, twelve, or a greater number of memory tiers.

The memory device 100 employs back-end-of-line (BEOL) memory cells contained exclusively within memory device layers 105, which are manufactured separately from the logic device layer 103. Providing the memory cells in memory device layers 105 that are manufactured separately from the logic device layer 103 layers allows the logic device layer 103 to be fabricated with a lower thermal budget, improving reliability, particularly when using advanced transistor technologies. In some embodiments, memory device 100 includes between one and two memory device layers 105. In alternative embodiments, memory device 100 includes three to four memory device layers 105, and in still other embodiments, the device comprises five or more memory device layers 105. Increasing the number of memory device layers 105 allows for increased total memory capacity through a greater number of memory cell tiers.

In some embodiments, each memory device layer 105 includes between two and six memory cell tiers. In some embodiments, each memory device layer 105 includes between three and four memory cell tiers. Increasing the number of memory cell tiers per memory device layer 105 reduces the total number of wafer bonding layers required, thereby decreasing the overall package height of the memory device 100. However, limiting the number of memory cell tiers per memory device layer 105 is beneficial for controlling wafer warpage during fabrication.

Providing memory cells in memory device layers that are separate from the logic device layer 103 offers an additional advantage: increased chip area devoted to memory cells. The total number of memory cells per tier is determined by the product of the number of rows (m) and the number of columns (n). In various embodiments, each memory tier may contain from about 512 million to about 16 billion memory cells. Other embodiments provide memory tiers having from about 32 billion to about 64 billion memory cells. In yet further embodiments, each memory tier includes at least about 128 billion memory cells.

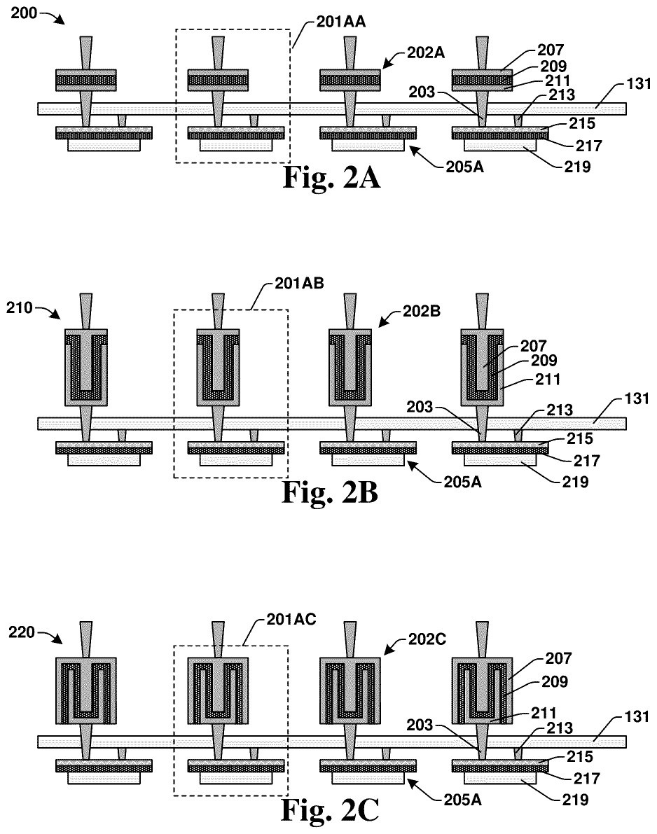

FIG. 2A is a cross-sectional view 200 illustrating a row of 1T1C memory cells 201AA disposed along a bitline segment 131. Each 1T1C memory cell 201AA includes a transistor 205A and a capacitor 202A. The transistor 205A is implemented as a bottom-gate transistor having a gate 219 electrically connected to a word line segment 121 (see FIG. 1A), a drain 213 electrically connected to the bitline segment 131, and a source 203 electrically coupled to the capacitor 202A. The transistor 205A further comprises a gate dielectric layer 217 and a channel layer 215 disposed above the gate 219. The channel layer 215 is formed from an oxide semiconductor or other suitable semiconductor material compatible with BEOL processing. The gate 219, the gate dielectric layer 217, and the channel layer 215 may be formed using physical vapor deposition (PVD), chemical vapor deposition (CVD), atomic layer deposition (ALD), or other suitable deposition techniques.

The capacitor 202A is configured as a planar metal-insulator-metal (MIM) capacitor having a first plate 211 electrically coupled to transistor 205A and a second plate 207 electrically coupled to a reference voltage (e.g., ground). The first plate 211 and the second plate 207 are separated by a capacitor dielectric 209. The first plate 211 and the second plate 207 can comprise conductive metals such as tungsten (W), ruthenium (Ru), titanium nitride (TiN), tantalum nitride (TaN), combinations thereof, or the like. In certain embodiments, the first plate 211 (bottom plate) has a thickness in the range of about 10 nm to about 200 nm, and the second plate 207 (top plate) has a thickness in the range of about 200 nm to about 1000 nm. The 1T1C memory cells 201AA may be DRAM cells in a DRAM device, in which case the capacitor dielectric 209 may comprise a high-κ dielectric material such as aluminum oxide (AlO), aluminum zirconium oxide (AlZrO), niobium oxide (NbO), or hafnium oxide (HfO), with a thickness typically ranging from about 3 nm to about 10 nm. In an alternative embodiment, the capacitor dielectric 209 comprises a ferroelectric material, such as lead zirconate titanate (PZT) or hafnium zirconium oxide (HfZrO₂), thereby configuring capacitor 202A to be operative as a ferroelectric capacitor for use in ferroelectric RAM (FeRAM). The layers of the capacitor 202A may be formed by PVD, CVD, ALD, or other suitable techniques.

FIG. 2B is a cross-sectional view 210 illustrating a row of 1T1C memory cells 201AB according to another embodiment. Each 1T1C memory cell 201AB comprises a transistor 205A and a trench MIM capacitor 202B. Trench MIM capacitors provide greater capacitance per unit area compared to planar MIM capacitors, but have greater vertical height. The memory device layers 105 (see FIG. 1), which lack FEOL semiconductor devices, are particularly suited for accommodating multiple tiers of memory cells utilizing trench MIM capacitors, as fewer routing layers are needed compared to device layers having FEOL semiconductor devices, leaving more vertical space for memory cells.

FIG. 2C is a cross-sectional view 220 illustrating a row of 1T1C memory cells 201AC according to yet another embodiment. Each memory cell 201AC comprises a transistor 205A and a coaxial trench MIM capacitor 202C. Coaxial trench MIM capacitors provide even greater capacitance density than basic trench or planar MIM capacitors but are more challenging to integrate within conventional process flows. The provision of the memory cells in the memory device layers 105 (see FIG. 1) permits BEOL processing specifically tailored for coaxial trench MIM capacitors without negatively impacting the metal interconnect structures of the logic device layer 103.

FIG. 2D is a cross-sectional view 230 illustrating a row of 1T1C memory cells 201BA according to another embodiment. Each memory cell 201BA comprises a transistor 205B and a capacitor 202A; however, capacitors 202B (FIG. 2B) or 202C (FIG. 2C) may alternatively be used. The transistors 205B are implemented as front-gate transistors, which generally offer superior switching performance compared to bottom-gate transistors but can be more difficult to integrate into a BEOL interconnect structure. The substrate-free memory device layers 105 (see FIG. 1), being separated from logic circuits, facilitate the integration of front-gate transistors within BEOL processing without adversely affecting the logic device layer 103 interconnect structure.

FIG. 2E is a cross-sectional view 240 illustrating a row of 1T1C memory cells 201CA according to yet another embodiment. Each memory cell 201CA includes a transistor 205C and a capacitor 202A; alternatively, capacitors 202B (FIG. 2B) or 202C (FIG. 2C) may be used. The transistor 205C is a dual-gate transistor comprising the gate 219 and the gate dielectric layer 217 over the channel layer 215 and a second gate 223 and a second gate dielectric layer 221 under the channel layer 215. Dual gate transistors enable precise threshold voltage tuning to achieve uniform memory cell characteristics. Although dual-gate transistors increase process complexity relative to bottom-gate or front-gate transistors, the absence of FEOL devices in memory device layers 105 (see FIG. 1) allows BEOL processes to be specifically optimized for fabricating reliable dual-gate transistor structures.

FIG. 2F is a cross-sectional view 250 illustrating a row of 1T1C memory cells 201DA according to another embodiment. Each memory cell 201DA includes a transistor 205D and a capacitor 202A; alternatively, capacitors 202B (FIG. 2B) or 202C (FIG. 2C) may be employed. The transistor 205D is a vertical-gate transistor, providing a narrower footprint compared to a bottom-gate or a front-gate transistor but presenting additional integration challenges. The memory device layers 105 (see FIG. 1), having no FEOL devices, enable specialized BEOL processing tailored for vertical-gate transistors, avoiding interference with logic device layer 103 interconnect fabrication.

FIG. 2G is a cross-sectional view 260 illustrating another embodiment of a row of 1T1C memory cells 201DA. In this embodiment, the transistor 205D and the capacitor 202A are both located underneath the bitline segment 131. By contrast, in the embodiment illustrated in FIG. 2F (cross-sectional view 250), both transistor 205D and capacitor 202A are positioned above the bitline segment 131. Further embodiments (FIGS. 2A-2E) illustrate alternative configurations, wherein one of the transistor 205 and the capacitor 202 is positioned above the bitline segment 131, and the other is positioned below. Each of these alternative arrangements can apply to any transistor-capacitor pair. Placing both the capacitor and the transistor above the bitline segment 131 typically shortens bitline routing, reduces RC delay, and enhances device speed. Conversely, placing both the capacitor and the transistor beneath the bitline segment 131 generally enables greater cell density but may require more advanced processing. A hybrid arrangement—wherein one of the capacitor or transistor is positioned above the bitline segment, and the other below—can offer a balanced trade-off between reduced routing complexity and manageable manufacturing complexity.

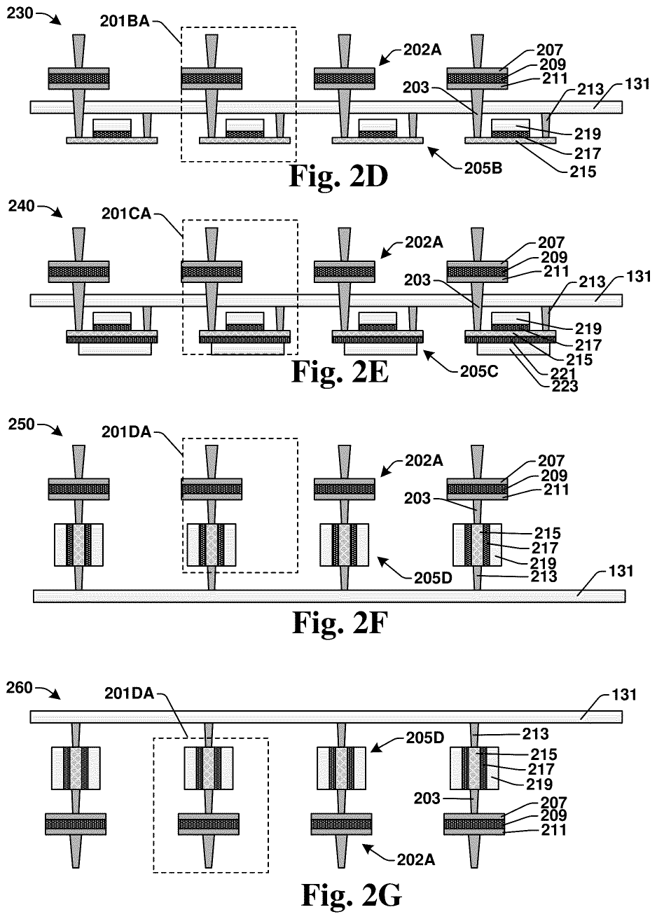

FIG. 3 provides a circuit diagram 300 for a 1T1C memory cell 201. The capacitor 202 can be charged to encode a data value of 1 and discharged to record a data value of 0. In a read operation, the bitline segment 131 is first pre-charged and then coupled to the capacitor 202 by closing the transistor 205, causing a change in voltage on the bitline segment 131. The change in voltage is indicative of the programming state is discriminated by a sense amplifier (not shown). However, if the parasitic capacitance 301 on the bitline segment 131 is large in comparison to the capacitor 202, the change in voltage may be too small to be reliably determined. The parasitic capacitance 301 depends on the number of memory cells 201 coupled to the bitline segment 131. This phenomenon tends to limit the number of memory cells 201 that can be added to the memory device 100 having all the sense amplifiers in a single logic device layer 103.

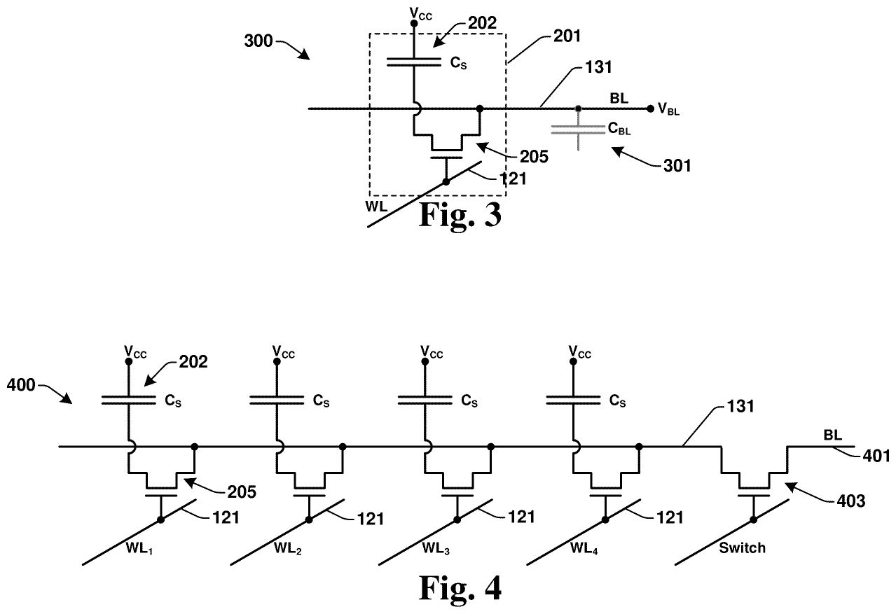

FIG. 4 provides a circuit diagram 400 illustrating a structure that overcomes this limitation. As shown in FIG. 4, switches 403 are configured to selectively isolate bitline segments 131 from the bitline 401. There can be one bitline 401 for each sense amplifier in the logic device layer 103 (see FIG. 1), and many bitline segments 131 selectively connected to the bitline 401 by switches 403. The bitline segments 131 that are isolated from the bitline 401 do not contribute to the parasitic capacitance 301 (see FIG. 3).

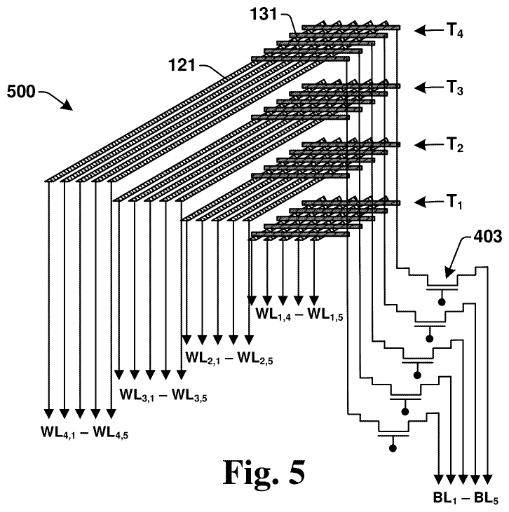

FIG. 5 provides a circuit diagram 500 that illustrates one embodiment of this concept. In this embodiment, each of the switches 403 selectively couples a set of bitline segments 131 distributed among tiers T₁-T₄ to one of the bitlines BL₁-BL₅. This configuration allows all the switches 403 in any one of the memory device layers 105A-105D (see FIG. 1) to be disposed at the same level, e.g., with the first or second redistribution layer, either above or below the memory cell tiers T₁-T₄.

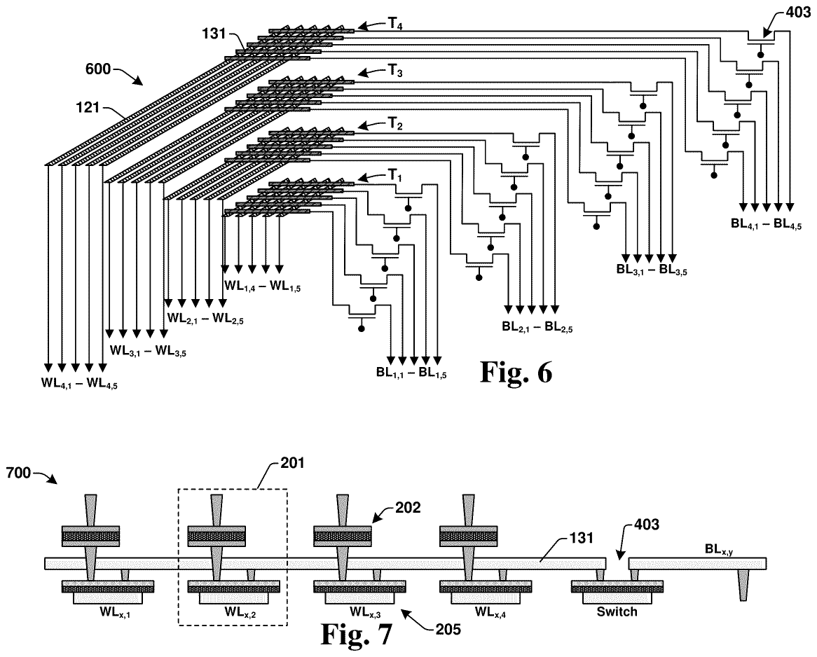

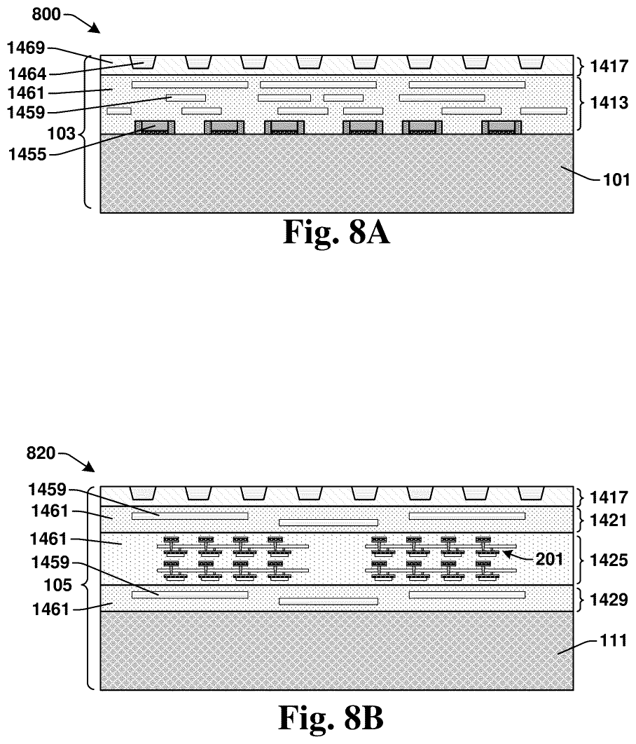

FIG. 6 provides a circuit diagram 600 that illustrates another way of implementing the switched 403. In this embodiment, distinct switches 403 are provided for each of the tiers T₁-T₄. This embodiment allows greater isolation of bitline segments 131. Moreover, as shown by the cross-sectional view 700 of FIG. 7, the switches 403 can have the same structure as, and be manufactured simultaneously with, the transistors 205 of the 1T1C memory cells 201.

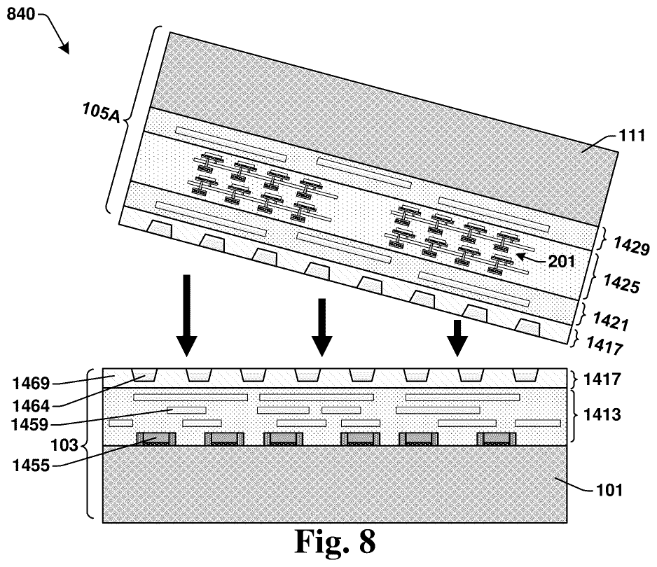

FIGS. 8A-14 provide a series of cross-sectional views 800-1400 that illustrate a memory device according to the present disclosure at various stages of manufacture according to a process of the present disclosure. Although FIGS. 8A-14 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 8A-14 are described in relation to a series of acts, it will be appreciated that the structures shown in FIGS. 8A-14 are not limited to a method of manufacture but rather may stand alone as structures separate from the method.

As shown by the cross-sectional views 800 and 820 of FIGS. 8A and 8B, the process begins with separate fabrication of the logic device layer 103 and a plurality of memory device layers 105. Fabricating the logic device layer 103 comprises FEOL processing of the substrate 101 followed by BEOL processing. The semiconductor substrate 101 may be a bulk semiconductor substrate or a semiconductor on insulator (SOI) substrate. At least an upper portion of the substrate 101 is a semiconductor. The semiconductor may be silicon (Si), a group III-V semiconductor (e.g., GaAs), some other binary semiconductor, a tertiary semiconductor (e.g., AlGaAs), a higher order semiconductor, the like, or any other suitable semiconductor. In some embodiments, the semiconductor substrate 101 is silicon (Si) or the like.

The semiconductor substrate 101 may be in the form of a wafer during FEOL processing. FEOL processing produces semiconductor devices 1455. The semiconductor devices 1455 produced by FEOL processing have elements such as channel regions, body regions, source regions, and drain regions within the semiconductor substrate 101. The semiconductor devices 1455 can include transistors, diodes, capacitors, memory cells, thyristors, resistors, the like, or any combination thereof, and. In some embodiments, FEOL processing is at a technology node that produces FinFETs or an even more advanced transistor type.

BEOL processing provides a BEOL metal interconnect structure 1413. A BEOL metal interconnect structure includes a plurality of metallization layers, each including conductive traces 1459 and intermetal dielectric 1461, and may also include a bonding layer 1417, which includes bond pads 1464 and bonding layer dielectric 1469. The conductive traces 1459 in adjacent metallization layers are interconnected by vias (not shown) in via layers. A metallization layer-via layer pair may be produced by a dual damascene process or other suitable processing. BEOL transistors, capacitors, and the like, when present, are disposed within the metallization and via layers of a BEOL metal interconnect structure.

The conductive traces 1459 can be copper (Cu), aluminum (Al), the like, or some other suitable metal. The intermetal dielectric 1461 can be silicon dioxide (SiO₂) or a low-κ dielectric. Examples of low-κ dielectrics include, without limitation, organosilicate glasses (OSG) such as carbon-doped silicon dioxide, fluorine-doped silicon dioxide (otherwise referred to as fluorinated silica glass (FSG), organic polymer low-κ dielectrics, and porous silicate glass. The BEOL metal interconnect structure 1413 interconnects the semiconductor devices 1455 to form circuits, including sense amplifiers and word line drivers.

With reference to FIG. 8B, fabricating the memory device layer 105 requires only BEOL processing. The substrate 111 is needed only for mechanical support. The substrate can be a semiconductor substrate for process compatibility but could alternatively be another type of substrate. BEOL processing of the memory device layer 105 produces, in order, a first RDL 1429, a memory layer 1425 including one or more tiers of memory cells 201, a second RDL 1421, and a bonding layer 1417. The memory cells 201 are disposed within a BEOL metal interconnect structure that includes metallization and via layers within the first RDL 1429, within the second RDL 1421, and within the memory layer 1425.

As shown by the cross-sectional view 840 of FIG. 8C, the process continues with inverting the memory device layer 105A, which is an instance of the memory device layer 105 of FIG. 8B, aligning it to, and bonding it with logic device layer 103. The bonding process may be metal-to-metal bonding, or both metal-to-metal and dielectric-to-dielectric bonding.

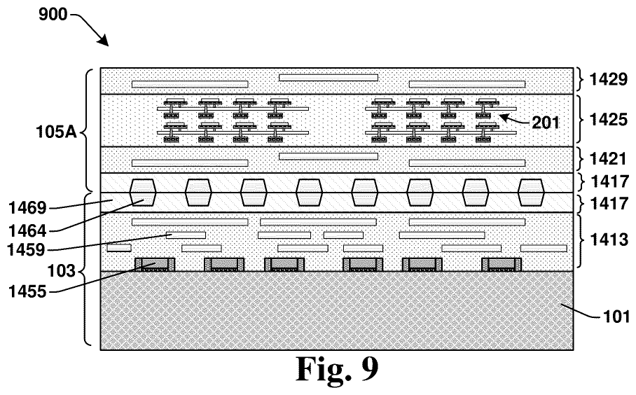

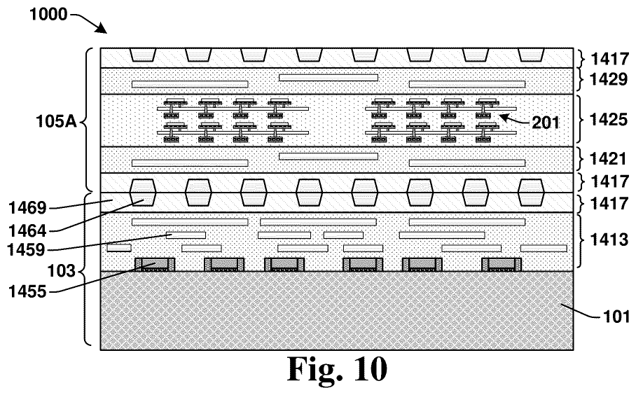

As shown by the cross-sectional view 900 of FIG. 9, after bonding the memory device layer 105A to the logic device layer 103, the substrate 111 (see FIG. 8C) of the memory device layer 105A is removed. The removal process may include one or more of grinding, chemical mechanical polishing (CMP), etching, or the like. The removal process exposes the first RDL 1429. As shown by the cross-sectional view 1000 of FIG. 10, another bonding layer 1417 is formed on the first RDL 1429. The substrate 111 may then be removed from the memory device layer 105B as shown in the cross-sectional views 900 of FIG. 9 and another bonding layer formed on the exposed surface as shown by the cross-sectional view 1000 of FIG. 10.

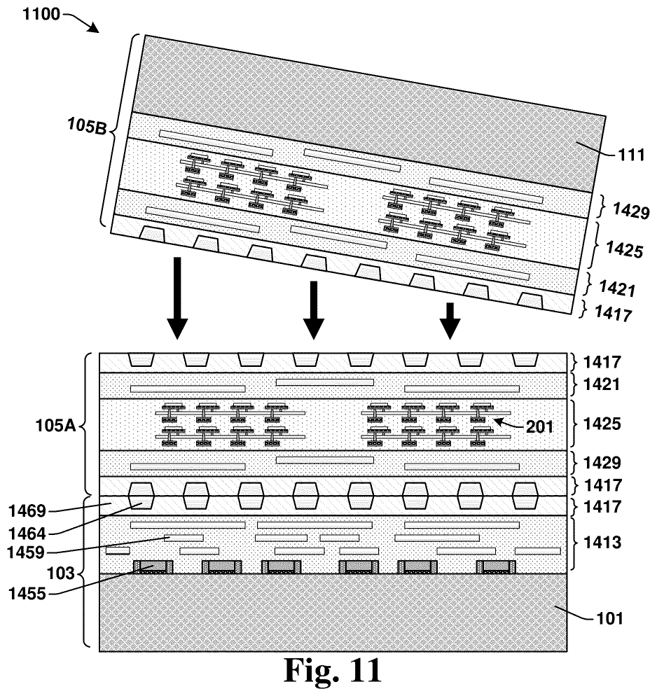

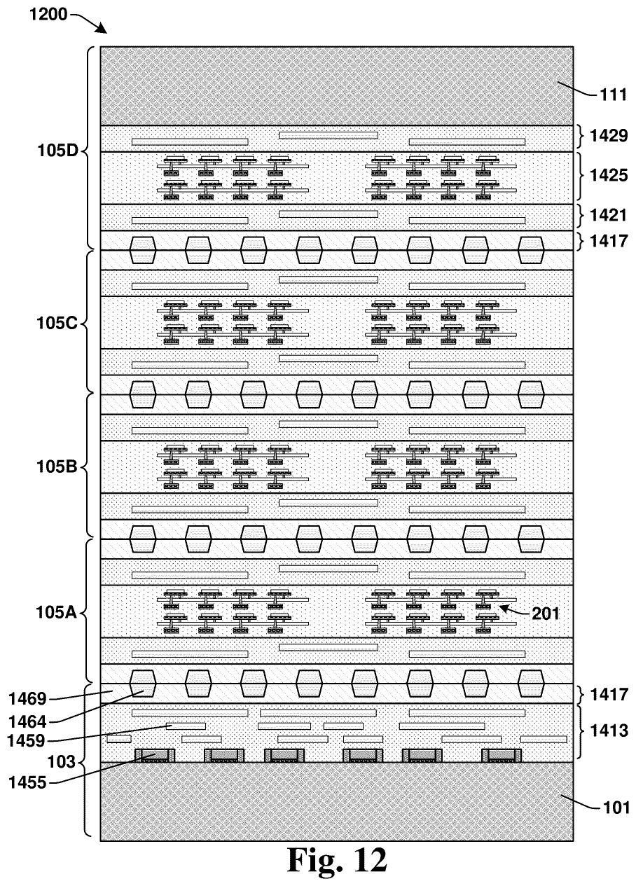

Another memory device layer 105B may then be added to the stack as shown by the cross-sectional view 1100 of FIG. 11. The substrate 111 may then be removed from that memory device layer, another bonding layer formed, and additional memory device layers 105C and 105D added in similar fashion as shown by the cross-sectional view 1200 of FIG. 12. The substrate 111 of the last-added memory device layer 105D is not removed.

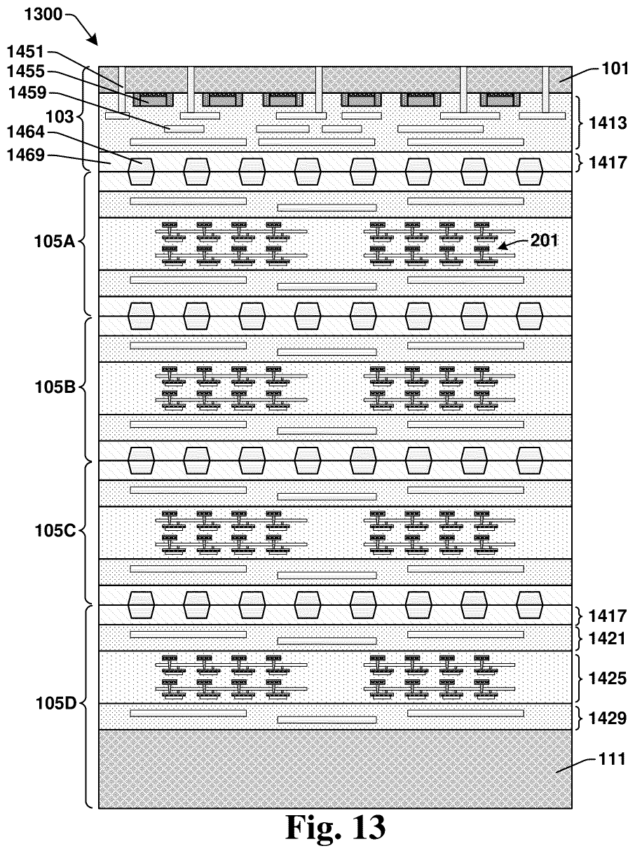

As shown by the cross-sectional view 1300 of FIG. 13, the partially manufactured device is inverted and the substrate 101 of the logic device layer 103 is thinned. Thinning may comprise grinding, CMP, or the like. After thinning, TSVs 1451 are formed through the substrate 101. Thinning can reduce the substrate 101 from an initial thickness of about 760 μm to a thickness in the range from about 1 μm to about 20 μm. In some embodiments, the substrate 101 is reduced to a thickness in the range from about 3 μm to about 6 μm. If the substrate 101 is thinned too much, the semiconductor devices 1455 may be damaged. If the substrate 101 is thinned too little, the TSVs 1451 may be difficult to form.

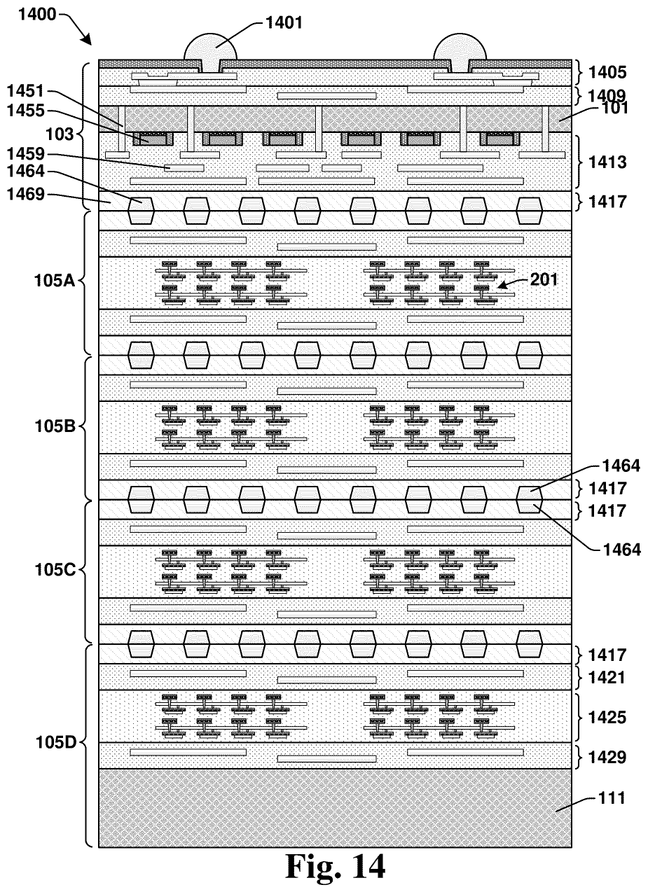

As shown by the cross-sectional view 1400 of FIG. 14, a redistribution layer 1409 can be formed on the back side of the substrate 101 followed by a layer 1405 that includes a passivation structure and solder bumps 1401.

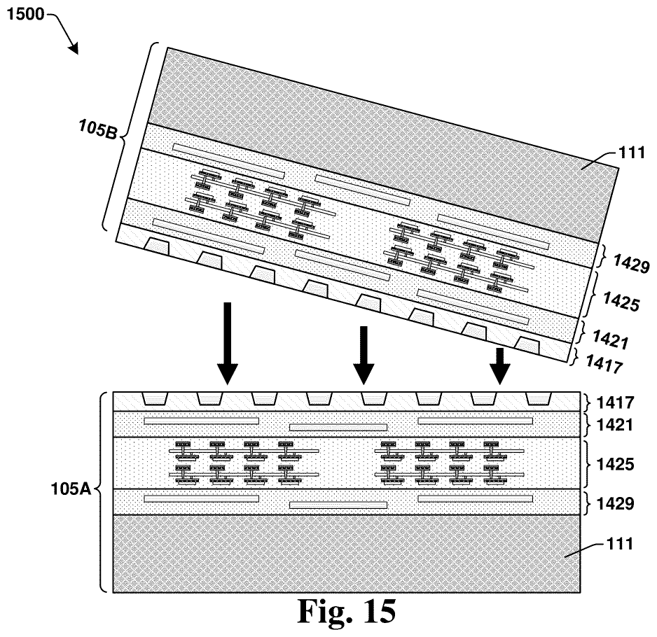

The cross-sectional views 800-1400 of FIGS. 8A-14 illustrate the logic-first process flow. The cross-sectional views 1500-1800 of FIG. 15-18 illustrate aspects of the logic-last process flow that differ from the logic-first process flow.

As shown by the cross-sectional view 1500 of FIG. 15, the logic-last process flow begins with inverting the memory device layer 105B and bonding it to the memory device layer 105A. The memory device layer 105A can have a different wiring structure from the memory device layers 105B-105D to provide the same connectivity as in the logic-first process flow.

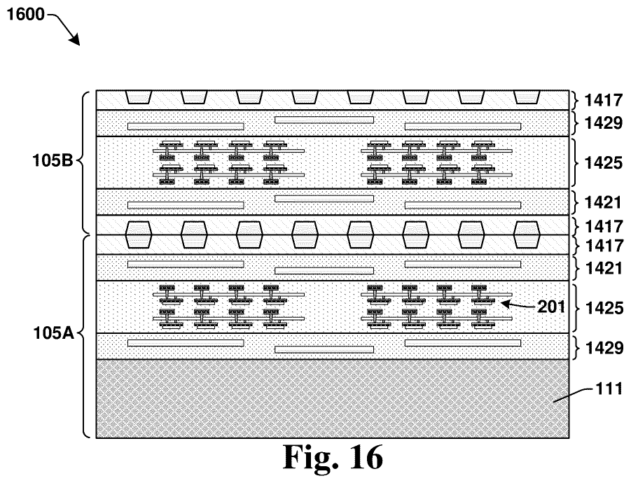

As shown by the cross-sectional view 1600 of FIG. 16, the substrate 111 is removed from the memory device layer 105B and replaced with a bonding layer 1417. This may be the same processing as shown by the cross-sectional views 900-1000 of FIGS. 9 and 10 in connection with the logic-first process-flow. Additional memory device layers 105C and 105D may be added to the stack in like fashion.

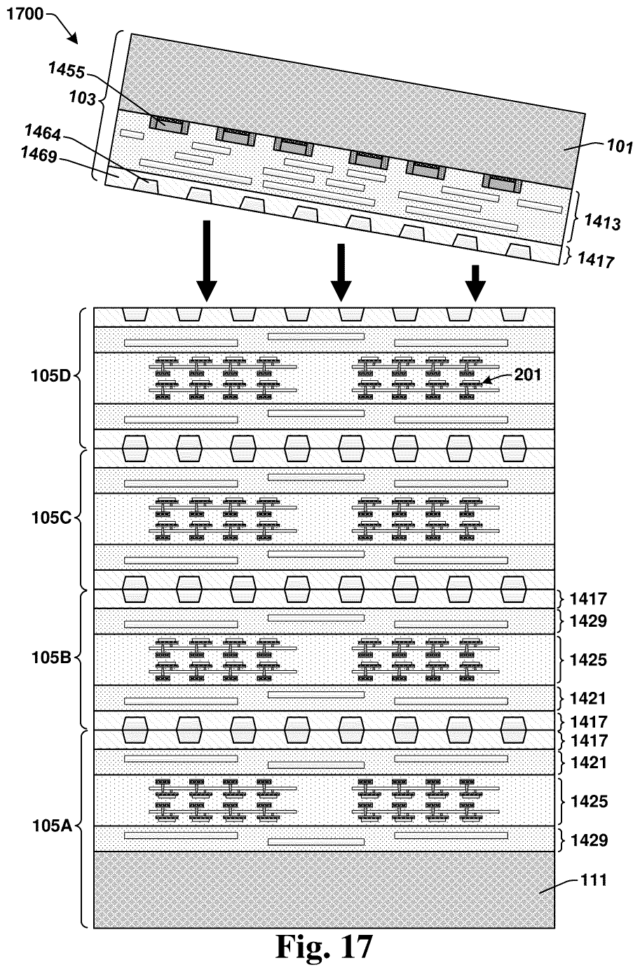

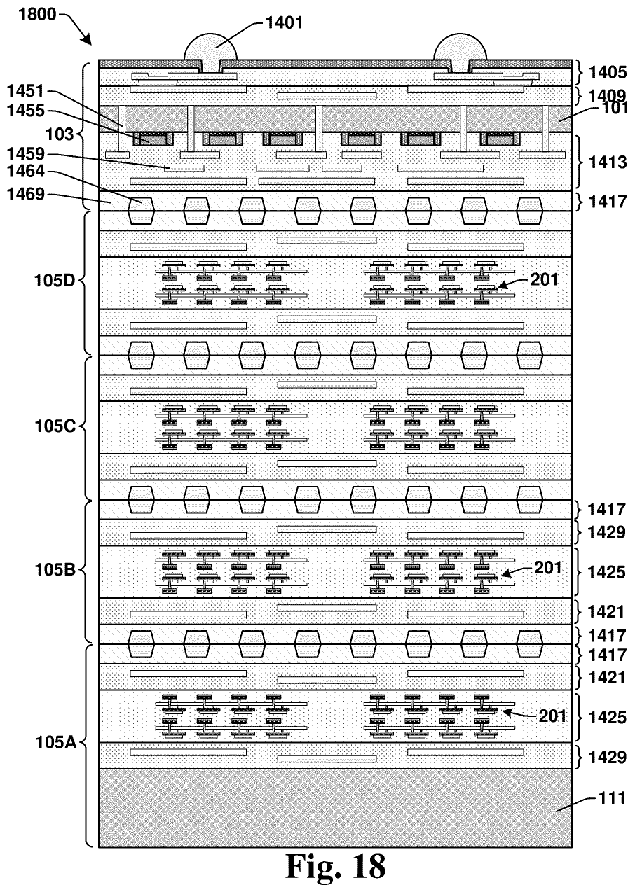

As shown by the cross-sectional view 1700 of FIG. 17, the logic device layer 103 may be inverted and bonded to the stack that includes the memory device layers 105A-105D. The semiconductor substrate 101 may then be thinned followed by formation of the redistribution layer 1409 and the layer 1405 that includes a passivation structure and solder bumps 1401 to form a memory device as shown by the cross-sectional view 1800 of FIG. 18.

As shown by the cross-sectional view 1800 of FIG. 18, the memory device produced with the logic-last process flow can be very similar to the memory device produced with the logic-last process flow, which is shown by the cross-sectional view 1400 or FIG. 14. However, there are some differences. In the memory device layer 105A shown by the cross-sectional view 1800 of FIG. 18, the memory cells 201 are inverted relative to the orientation of memory cells 201 in the memory device layer 105B-105D. In addition, the memory device layer 105A has a different arrangement of wiring (not shown) that accounts for the different orientation of memory device layer 105A within the stack.

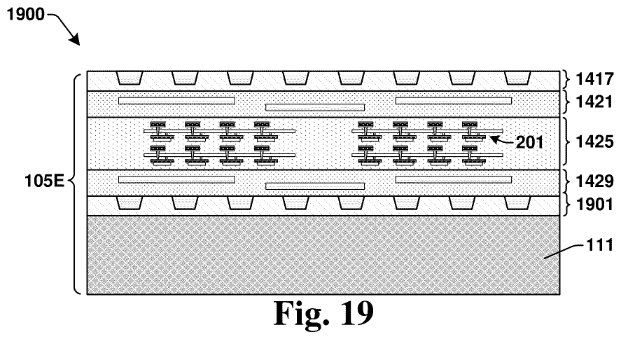

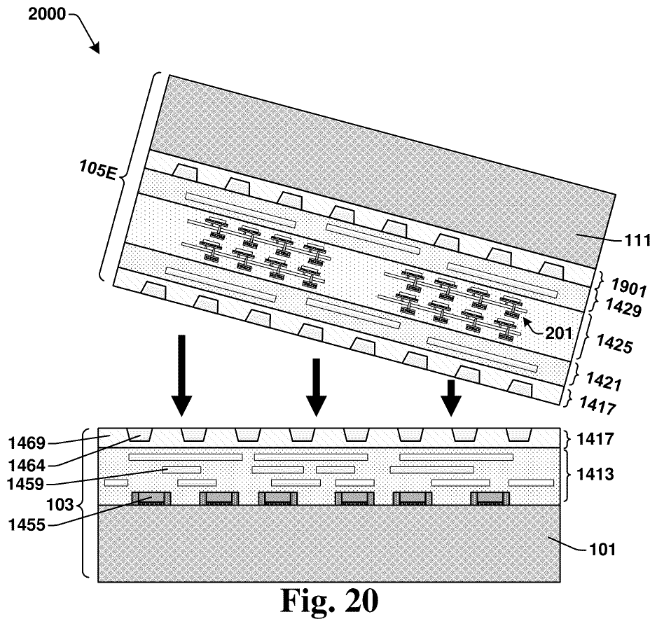

The cross-sectional views 1900-2200 of FIGS. 19-22 show a variation on the logic-first process flow. As shown by the cross-sectional view 1900 of FIG. 19, in this variation a bonding layer 1901 is formed between the first RDL 1429 and the substrate 111 when fabricating the memory device layers 105E. As shown by the cross-sectional view 2000 of FIG. 20, one of the memory device layers 105E is bonded to the logic device layer 103.

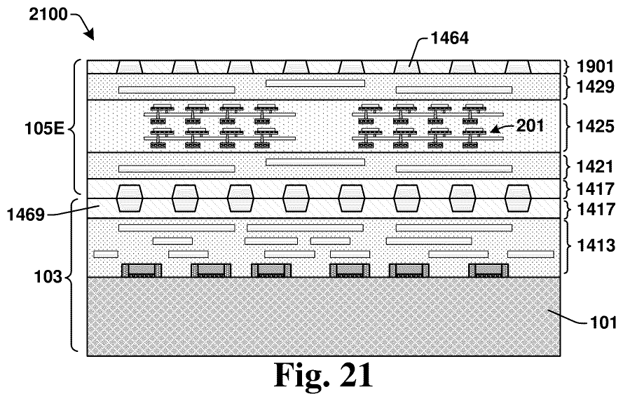

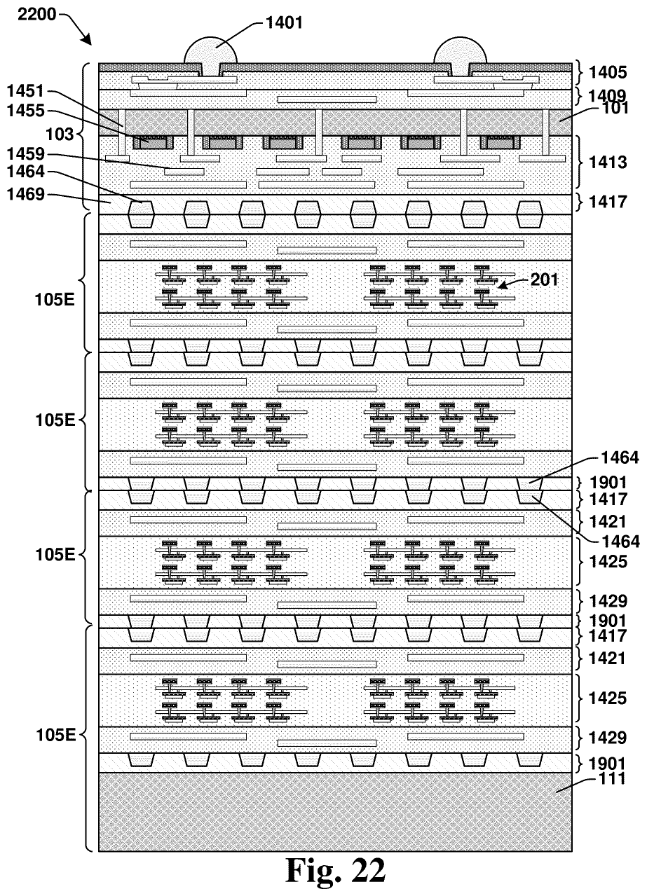

As shown by the cross-sectional view 2100 of FIG. 21, the process of removing the substrate 111 from the memory device layers 105E exposes the bonding layer 1901 and the bond pads 1464 within that layer. This contrasts with the process shown by the cross-sectional views 900 and 1000 of FIGS. 9 and 10, wherein a bonding layer 1417 is formed after removal of the substrate 111. The process may continue as previously described for the logic-first process flow to provide a memory device as shown by the cross-sectional view 2200 of FIG. 22.

As shown by the cross-sectional view 2200 of FIG. 22, the resulting memory device is similar to the one shown in the cross-sectional view 1400 of FIG. 14 but differs in the structure of the bonding layers. In the cross-sectional view 1400 of FIG. 14, bond pads 1464 are symmetrical about each bonding interface between adjacent memory device layers 105. In the cross-sectional view 2200 of FIG. 22, they are asymmetrical. In the cross-sectional view 1400 of FIG. 14, the bond pads 1464 all taper to become wider as they approach the bonding interface. In the cross-sectional view 2200 of FIG. 22, one set of bond pads 1464 taper to become wider as they approach the bonding interface, and the other set taper to become narrower as they approach the bonding interface.

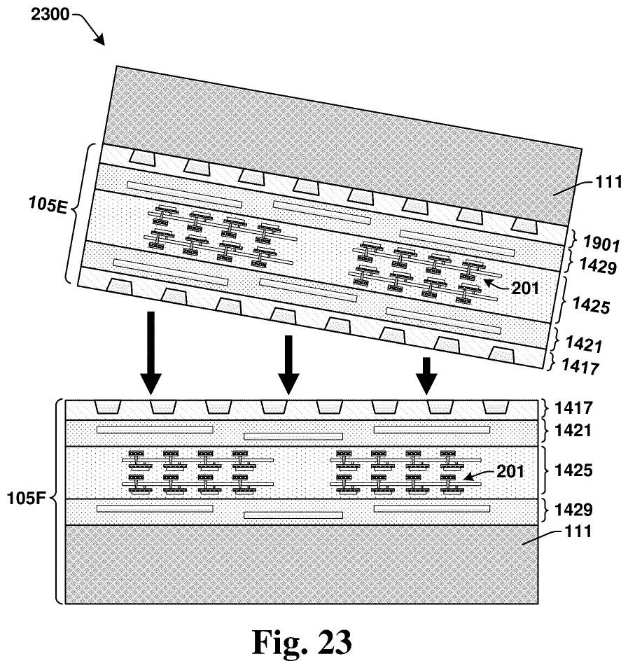

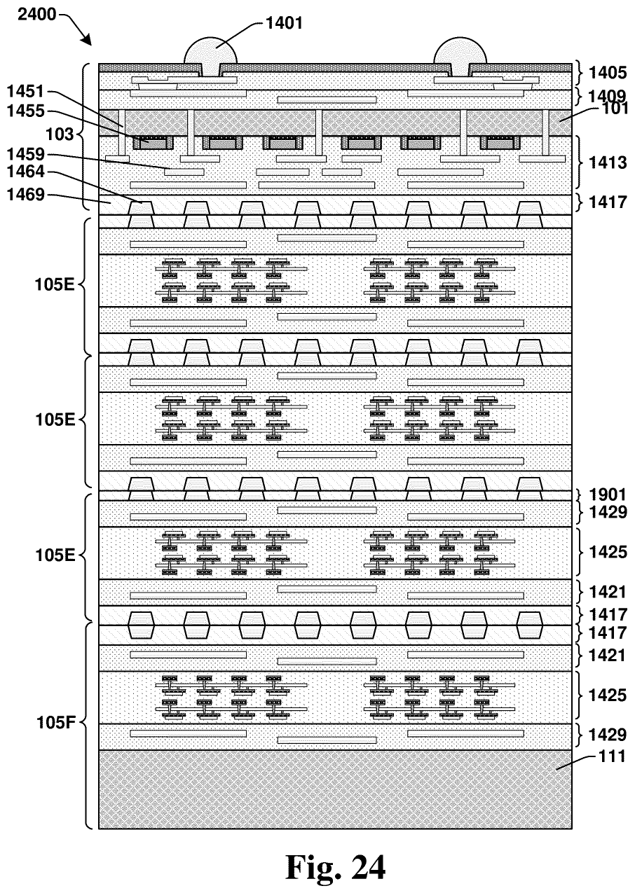

The cross-sectional views 2300-2400 of FIGS. 23-24 show the logic-last process flow for the case in which the bonding layers 1901 are formed during BEOL processing of the memory device layers 105. As shown by the cross-sectional view 2300 of FIG. 23, one of the memory device layers 105E is inverted and bonded to a memory device layer 105F. The memory device layer 105F is like the memory device layers 105E, but may have a different wiring structure and may lack the bonding layer 1901. The process continues as previously described for the logic-last process flow. The cross-sectional view 2400 of FIG. 24 provides an example of the resulting structure.

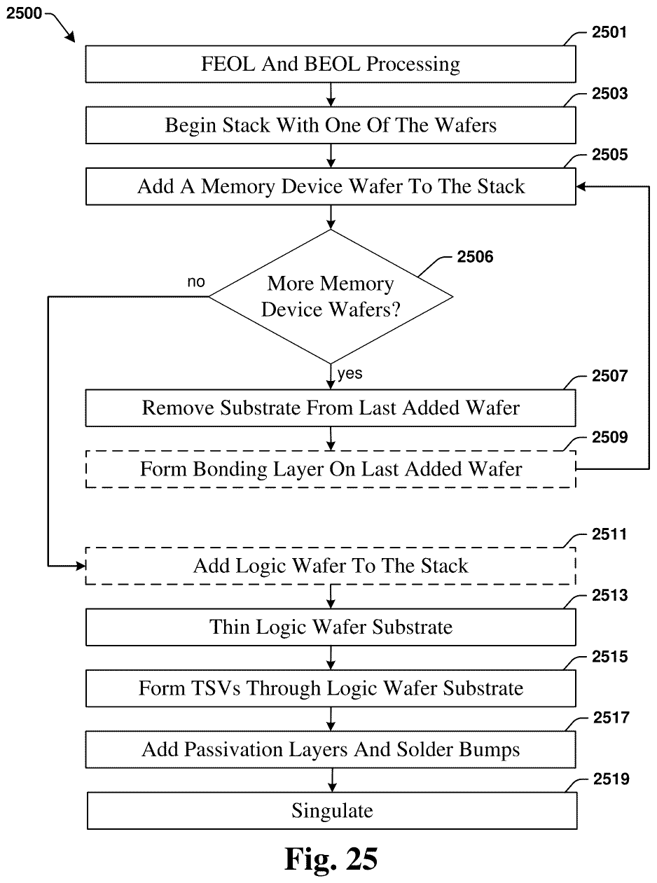

FIG. 25 provides a flow diagram for a method 2500 of forming a memory device according to some embodiments. While the method 2500 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2500 begins with act 2501, FEOL and BEOL processing of memory and logic device wafers. Only the logic device wafer requires FEOL processing, and different BEOL processes corresponding to distinct process technology nodes may be applied to the memory and logic device wafers. The cross-sectional view 800, 820, and 1900 of FIGS. 8A, 8B, and 1900 provide examples of memory and logic device wafers after FEOL and BEOL processing.

The method 2500 continues with acts 2503 and 2505, beginning a stack by bonding one of the memory device wafer to either a logic device wafer (logic-first process sequence) or another memory device wafer (logic-last process sequence). The cross-sectional views 840 and 2000 of FIGS. 8C and 20 provide examples for the logic-first process sequence and the cross-sectional views 1500 and 2300 of FIGS. 15 and 23 provide examples for the logic-last process sequence.

Act 2506 is a decision block. If more memory device wafers are to be added to the stack, the process continues with act 2507, removing the substrate from the last memory device wafer to have been added to the stack, act 2509, forming a bonding layer on the wafer (unless the bonding layer was previously formed and is exposed after the substrate is removed), and a repetition of act 2505, adding another memory device layer to the stack. The cross-sectional views 900-1200, 1600-1700 and 2100-2200, and 2400 of FIGS. 9-12, 16-17, 21-22, and 24 provide examples of these processes.

After all the memory device wafers have been added to the stack, the process continues with act 2511 for the logic-last process sequence and act 2513 for the logic-first process sequence. Act 2511 is adding a logic device wafer to the stack. This act is only used for the logic-last process sequence. The cross-sectional views 1700 and 2400 of FIGS. 17 and 24 provide examples.

Act 2513 is thinning the substrate of the logic device wafer. Act 2515 is forming TSVs through the logic device wafer substrate. Act 2517 is forming redistribution layers, passivation layers, solder bumps, or the like on the back of the logic device wafer substrate. The cross-sectional views 1400, 1800, 2200, and 2400 of FIGS. 14, 18, 22, and 24 provide examples of the resulting memory devices. Act 2519 is singulation.

Some aspects of the present disclosure relate to a memory device that includes a stack and word lines and bitline segments between a first semiconductor substrate and a second substrate. Integrated circuits including sense amplifiers have elements in the first semiconductor substrate. The stack includes memory tiers and bonding tiers within a composite dielectric structure. The memory tiers comprise 1T1C memory cells. The bonding tiers comprise bond pads bonded to other bond pads in the stack at bonding interfaces. One of the bonding interfaces is between the memory tiers and the first semiconductor substrate. The composite dielectric structure extends from the first semiconductor substrate to the second substrate. Each 1T1C memory cell is at a juncture between one of the word lines and one of the bitline segments and each bitline segment is electrically connected, either directly or through a switch, to one of the sense amplifiers.

In some embodiments, there are a plurality of the bonding interfaces, and groups of one or more of the memory tiers are interleaved with the bonding interfaces. In some embodiments, the groups of one or more of the memory tiers each include a plurality of the memory tiers. In some embodiments, are at least three of the bonding interfaces and twelve of the memory tiers. In some embodiments, the 1T1C memory cells comprise trench MIM capacitors. In some embodiments, the 1T1C memory cells comprise vertical-gate transistors.

In some embodiments, the memory device includes first and second bitline transistors. The first bitline transistor selectively couples one of the bitline segments to a first terminal of one of the sense amplifiers, and the second bitline transistor selectively couples a second of the bitline segments to the first terminal. In some embodiments, the first bitline transistor and the second bitline transistor are in the memory tiers. In some embodiments, there are through substrate vias extending through the first semiconductor substrate. In some embodiments, the 1T1C memory cells in the memory tiers closest to the first semiconductor substrate have an opposite vertical orientation from the 1T1C memory cells in the other memory tiers. In some embodiments, the memory tiers are separated from the bonding tiers by metallization layers.

Some aspects of the present disclosure relate to a memory device including a logic die and a plurality of memory dies bonded to the logic die in a stack. The logic die includes front-end-of-line (FEOL) logic circuits, wherein the FEOL logic circuits include sense amplifiers and word line drivers. The memory dies each include one or more tiers of back-end-of-line (BEOL) 1T1C memory cells. The plurality of memory dies include middle memory dies and an end memory die. The middle memory dies are disposed between the logic die and the end memory die. Each middle memory die includes an upper bonding tier and a lower bonding tier, with no intervening substrate. The upper bonding tier and the lower bonding tier are on opposite faces of the middle memory die. The sense amplifiers and the word line drivers are configured to control the 1T1C memory cells.

Some aspects of the present disclosure relate to a method of manufacturing memory device. The method includes manufacturing a logic device layer including front-end-of-line (FEOL) logic circuits on a semiconductor substrate, manufacturing a plurality of memory device layers, each including one or more tiers of back-end-of line (BEOL) memory cells over a memory device substrate and a first bonding layer, and forming the logic device layer and the plurality of memory device layers into a stack. The process of forming the stack includes: bonding one of the memory device layers to the stack through the first bonding layer, removing the memory device substrate from the memory device layer, and forming a second bonding layer on the memory device layer.

Some aspects of the present disclosure relate to a method of manufacturing memory device. The method includes manufacturing a logic device layer and first and second memory device layer. Manufacturing the logic device layer includes front-end-of-line (FEOL) processing and back-end-of line (BEOL) processing. The logic device layer includes a logic device substrate and an integrated circuit with semiconductor devices formed by the FEOL processing. Manufacturing the first memory device layer includes BEOL processing. The first memory device layer comprises a first memory device substrate and a first plurality of memory cell layers formed over the first memory device substrate by the BEOL processing. Manufacturing the second memory device layer includes BEOL processing. The second memory device layer includes a second memory device substrate and a second plurality of memory cell layers formed over the second memory device substrate by the BEOL processing. Each memory cell layer comprises a distinct array of memory cells. The logic device layer, the first memory device layer, and the second memory device layer are vertically stacked and bonded together by a process that includes removing the first memory device substrate from the first memory device layer.

In some embodiments, the BEOL processing used to manufacture the logic device layer has a lower thermal budget than the BEOL processing used to manufacture the first memory device layer. In some embodiments, vertically stacking and bonding together the logic device layer, the first memory device layer, and the second memory device layer comprises first bonding the first memory device layer to the logic device layer, removing the first memory device substrate from the first memory device layer, and then bonding the second memory device layer to the first memory device layer. In some embodiments, manufacturing the first memory device layer using BEOL processing comprises forming a stack including in order over the first memory device substrate: a first redistribution layer, the first plurality of memory cell layers, a second redistribution layer, and an upper bonding layer. In some embodiments, manufacturing the first memory device layer using BEOL processing further comprises forming a lower bonding layer between the first memory device substrate and the first redistribution layer.

In some embodiments, manufacturing the first memory device layer further comprises forming a switch, wherein the switch selectively couples a bitline segment in one of the first plurality of memory cell layers from a sense amplifier in the logic device layer. In some embodiments, the memory cells each comprise a memory cell transistor and a memory cell capacitor, and the switch is manufactured simultaneously with one of the memory cell transistors. In some embodiments, the method further includes thinning the logic device substrate and forming a through substrate via through the logic device substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first substrate comprising logic circuits, including sense amplifiers;
a stack over the first semiconductor substrate, wherein:
the stack comprises memory tiers and bonding tiers within a composite dielectric structure;
the memory tiers comprise memory cells;
the bonding tiers comprise bond pads bonded to other bond pads in the stack at bonding interfaces; and
one of the bonding interfaces is between the memory tiers and the first semiconductor substrate;
a second substrate over the stack, wherein the composite dielectric structure extends from the first semiconductor substrate to the second substrate; and
word lines and bitline segments, wherein each memory cell is at a juncture between one of the word lines and one of the bitline segments and each bitline segment is electrically connected, either directly or through a switch, to one of the sense amplifiers.

2. The integrated circuit device of claim 1, wherein there are a plurality of the bonding interfaces, and groups of one or more of the memory tiers are interleaved with the bonding interfaces.

3. The integrated circuit device of claim 2, wherein the groups of one or more of the memory tiers each include a plurality of the memory tiers.

4. The integrated circuit device of claim 3, wherein there are at least three of the bonding interfaces and twelve of the memory tiers.

5. The integrated circuit of claim 3, wherein the memory cells comprise trench MIM capacitors.

6. The integrated circuit of claim 3, wherein the memory cells comprise vertical-gate transistors.

7. The integrated circuit of claim 1, further comprising:
a first bitline transistor, wherein the first bitline transistor selectively couples one of the bitline segments to a first terminal of one of the sense amplifiers; and
a second bitline transistor, wherein the second bitline transistor selectively couples a second of the bitline segments to the first terminal.

8. The integrated circuit of claim 7, wherein the first bitline transistor and the second bitline transistor are in the memory tiers.

9. The integrated circuit of claim 1, further comprising through substrate vias extending through the first semiconductor substrate.

10. The integrated circuit of claim 1, wherein the memory cells in the memory tiers closest to the first semiconductor substrate have an opposite vertical orientation from the memory cells in the other memory tiers.

11. The integrated circuit of claim 1, wherein the memory tiers are separated from the bonding tiers by metallization layers.

12. A method of manufacturing an integrated circuit, comprising:
manufacturing a logic device layer including front-end-of-line (FEOL) logic circuits on a semiconductor substrate;
manufacturing a plurality of memory device layers, each comprising one or more tiers of back-end-of line (BEOL) memory cells over a memory device substrate, and a first bonding layer over the BEOL memory cells; and
forming the logic device layer and the plurality of memory device layers into a stack that includes:
bonding one of the memory device layers to the stack through the first bonding layer;
removing the memory device substrate from the memory device layer; and
forming a second bonding layer on the memory device layer.

13. A method of manufacturing and integrated circuit, the method comprising:
manufacturing a logic device layer using front-end-of-line (FEOL) processing and back-end-of line (BEOL) processing, wherein the logic device layer comprises a logic device substrate and an integrated circuit with semiconductor devices formed by the FEOL processing;
manufacturing a first memory device layer using BEOL processing, wherein the first memory device layer comprises a first memory device substrate and a first plurality of memory cell layers formed over the first memory device substrate by the BEOL processing, wherein each memory cell layer comprises a distinct array of memory cells;
manufacturing a second memory device layer using BEOL processing, wherein the second memory device layer comprises a second memory device substrate and a second plurality of memory cell layers formed over the second memory device substrate by the BEOL processing, wherein each memory cell layer comprises a distinct array of memory cells; and
stacking and bonding together the logic device layer, the first memory device layer, and the second memory device layer by a process that include removing the first memory device substrate from the first memory device layer.

14. The method of claim 13, wherein the BEOL processing used to manufacture the logic device layer has a lower thermal budget than the BEOL processing used to manufacture the first memory device layer.

15. The method of claim 13, wherein vertically stacking and bonding together the logic device layer, the first memory device layer, and the second memory device layer comprises first bonding the first memory device layer to the logic device layer, removing the first memory device substrate from the first memory device layer, and then bonding the second memory device layer to the first memory device layer.

16. The method of claim 13, wherein manufacturing the first memory device layer using BEOL processing comprises forming a stack including in order over the first memory device substrate: a first redistribution layer, the first plurality of memory cell layers, a second redistribution layer, and an upper bonding layer.

17. The method of claim 16, wherein manufacturing the first memory device layer using BEOL processing further comprises forming a lower bonding layer between the first memory device substrate and the first redistribution layer.

18. The method of claim 13, wherein manufacturing the first memory device layer further comprises forming a switch, wherein the switch selectively couples a bitline segment in one of the first plurality of memory cell layers from a sense amplifier in the logic device layer.

19. The method of claim 18, wherein the memory cells each comprise a memory cell transistor and a memory cell capacitor, and the switch is manufactured simultaneously with one of the memory cell transistors.

20. The method of claim 13, further comprising thinning the logic device substrate and forming a through substrate via through the logic device substrate.
